(19) United States
(12) Patent Application Publication
(10) Pub. No.: US 2021/0067169 A1
(43) Pub. Date: Mar. 4, 2021

(54) SIGNAL PROCESSING DEVICE

(71) Applicants: Kabushiki Kaisha Toshiba, Tokyo (JP); Toshiba Electronic Devices & Storage Corporation, Tokyo (JP)

(72) Inventor: Manabu Yamada, Ota Tokyo (JP)

(21) Appl. No.: 16/784,522

(22) Filed: Feb. 7, 2020

(30) Foreign Application Priority Data
Aug. 28, 2019 (JP) 2019-155517

(51) Int. Cl. H03M 1/78; H03M 1/06

(52) U.S. Cl. CPC H03M 1/785; H03M 1/0626

(57) ABSTRACT

A signal processing circuit includes first and second resistors between an input end terminal and an output end terminal, a filter circuit that has a capacitive element that is connected to connection terminals of the first and second resistors, and an amplification circuit that is connected to the filter circuit. A cutoff frequency of the filter circuit is set by values of the first resistor and the capacitive element and a gain of the amplification circuit is set by values of the first and second resistors and a value of a feedback resistor.

### CROSS-REFERENCE TO RELATED APPLICATIONS

This application is based upon and claims the benefit of priority from Japanese Patent Application No. 2019-155517, filed on Aug. 28, 2019; the entire contents of which are incorporated herein by reference.

### FIELD

The present embodiment generally relates to a signal processing device.

### BACKGROUND

A signal processing circuit that includes a filter circuit that is provided in a front part of an amplification circuit and an AD converter that digitally converts an output signal of the amplification circuit has been disclosed conventionally. In general, a filter circuit is used to eliminate noise and supply a desired input signal to an amplification circuit. Furthermore, an AD converter digitally converts an output signal of an amplification circuit by using a sampling signal with a predetermined frequency. A functional signal processing device is desired that effectively utilizes a filter circuit and includes an amplification circuit and an AD converter.

### BRIEF DESCRIPTION OF THE DRAWINGS

FIG. 1 is a diagram illustrating a signal processing device according to a first embodiment.

FIG. 2 is a diagram schematically illustrating a frequency characteristic of a filter circuit.

FIG. 3 is a Bode diagram for schematically explaining a phase margin.

FIG. 4 is a diagram illustrating a signal processing device according to a second embodiment.

FIG. 5 is a diagram illustrating a signal processing device according to a third embodiment.

### DETAILED DESCRIPTION

According to one embodiment, a signal processing circuit includes a filter circuit that includes a first resistor that is provided between a first input terminal and a first connection terminal, a second resistor that is provided between the first connection terminal and a first output terminal, and a capacitive element with one terminal that is connected to the first connection terminal, and an amplification circuit that has a first input end connected to the first output terminal and an output end and is provided with a feedback resistor that is connected between the first input end and the output end, wherein a cutoff frequency of the filter circuit is set by a resistance value of the first resistor and a capacitance value of the capacitive element and a gain of the amplification circuit is set by a ratio of a total value of resistance values of the first resistor and the second resistor and a resistance value of the feedback resistor.

Hereinafter, a-signal processing device according to any of embodiments will be explained in detail with reference to the accompanying drawings. Additionally, the present invention is not limited by such an embodiment.

### First Embodiment

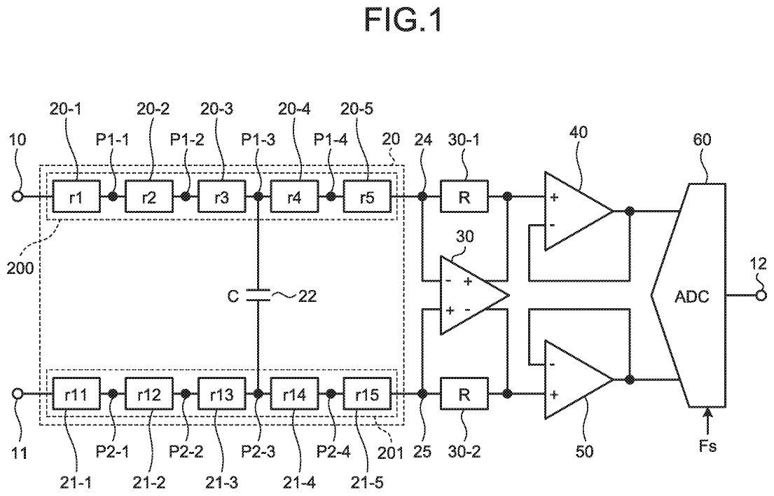

FIG. 1 is a diagram illustrating a signal processing device according to a first embodiment. A signal processing device according to the present embodiment has a filter circuit 20, a fully differential type operational amplifier 30, buffer amplifiers 40, 50, and a differential input type AD converter 60.

The filter circuit 20 is connected to input terminals 10, 11. For example, a differential signal is supplied between the input terminals 10, 11. It has a ladder resistance circuit 200 where a plurality of resistance elements 20-1 to 20-5 are connected in series, between the input terminal 10 and an output terminal 24. Resistance values r1 to r5 of the resistance elements 20-1 to 20-5 are set at, for example, identical resistance values. The resistance elements 20-1 to 20-5 that are provided back and forth are connected by connection terminals P1-1 to P1-4.

It has a ladder resistance circuit 201 where a plurality of resistance elements 21-1 to 21-5 are connected in series, between the input terminal 11 and an output terminal 25. Similarly to the ladder resistance circuit 200, resistance values r11 to r15 of the resistance elements 21-1 to 21-5 are set at, for example, identical resistance values. The resistance elements 21-1 to 21-5 that are provided back and forth are connected by connection terminals P2-1 to P2-4.

In the present embodiment, a resistance value from the input terminal 10 to the output terminal 24 and a resistance value from the input terminal 11 to the output terminal 25 are set identically. Therefore, resistance values of the resistance elements 20-1 to 20-5 and the resistance elements 21-1 to 21-5 are set identically.

A capacitive element 22 is connected between the connection terminal P1-3 of the resistance elements 20-3 and 20-4 of the ladder resistance circuit 200 and the connection terminal P2-3 of the resistance elements 21-3 and 21-4 of the ladder resistance circuit 201. In the present embodiment, an RC low-pass filter is composed of the resistance elements 20-1 to 20-3 from the input terminal 10 to the connection terminal P1-3, the resistance elements 21-1 to 21-3 from the input end terminal 11 to the connection terminal P2-3, and the capacitive element 22. That is, it has a so-called balance type RC filter circuit. The filter circuit 20 is conveniently provided that includes the resistance elements 20-4 to 20-5 from the connection terminal P1-3 to the output terminal 24 and the resistance elements 21-4 to 21-5 from the connection terminal P2-3 to the output terminal 25.

As a resistance value from the input terminal 10 to the connection terminal P1-3 and a resistance value from the input end terminal 11 to the connection terminal P2-3 are provided as R1, a cutoff frequency Fc for a differential signal of the filter circuit 20 is represented by formula (1).

Fc=1/(2π×R1×2×C) (1)

Herein, C is a capacitance value of the capacitive element 22.

That is, as indicated in formula (1), a value twice as much as a capacitance value C of the capacitive element 22 contributes to setting of a cutoff frequency Fc. Therefore, it is possible to set a cutoff frequency Fc at a low frequency by efficiently reflecting a capacitance value C of the capacitive element 22, so that it is possible to efficiently eliminate noise that is included in an input signal.

A cutoff frequency Fc is set by taking into consideration a frequency of a sampling signal Fs of the differential input type AD converter 60 at a back part. Specifically, a cutoff frequency Fc is set by adjusting a resistance value R1 and a capacitance value C in such a manner that noise with a frequency that approximates a frequency of a sampling signal Fs is eliminated from an input signal that is applied between the input terminals 10, 11.

In a case where noise with a frequency that approximates a frequency of a sampling signal Fs is included in an input signal, an output of the differential input type AD converter 60 varies with a slight variation of timing of sampling in the differential input type AD converter 60. A variation of timing of sampling is caused by, for example, a temperature change. Therefore, a cutoff frequency Fc of the filter circuit 20 is set at a sufficiently low value with respect to a frequency of a sampling signal Fs to eliminate noise with a frequency that approximates the frequency of the sampling signal Fs, so that it is possible to avoid strict control of timing of sampling in the differential input type AD converter 60. Thereby, a margin level of a design is improved. Additionally, Fs may conveniently be used for a sampling signal and a frequency thereof below.

The output terminal 24 is connected to an inverting input end (−) of the fully differential type operational amplifier 30 and the output terminal 25 is connected to a non-inverting input end (+). A feedback resistor 30-1 is connected between an inverting input end (−) and a non-inverting output end (+) and a feedback resistor 30-2 is connected between a non-inverting input end (+) and an inverting output end (−). An inverting output end (−) outputs a signal with a phase opposite to that of an output signal of a non-inverting output end (+).

A gain of an amplification circuit that includes the fully differential type operational amplifier 30 is set by a ratio of a resistance value of the ladder resistance circuit 200, that is, a total value of resistance values of the resistance elements 20-1 to 20-5 (=r1+r2+r3+r4+r5) and a resistance value R of the feedback resistor 30-1 and a ratio of a resistance value of the ladder resistance circuit 201, that is, a total value of resistance values of the resistance elements 21-1 to 21-5 (=r11+r12+r13+r14+r15) and a resistance value R of the feedback resistor 30-2.

An output signal of a non-inverting output end (+) of the fully differential type operational amplifier 30 is supplied to a non-inverting input end (+) of the buffer amplifier 40 and an output signal of an inverting output end (−) of the fully differential type operational amplifier 30 is supplied to a non-inverting input end (+) of the buffer amplifier 50.

Outputs of the buffer amplifiers 40 and 50 are supplied to the differential input type AD converter 60. The differential input type AD converter 60 samples output signals of the buffer amplifiers 40 and 50 by a sampling signal Fs with a predetermined frequency, converts it into a digital signal, and supplies it to an output terminal 12.

According to the first embodiment, the ladder resistance circuits 200, 201 of the filter circuit 20 are used for setting of a gain of the amplification circuit that includes the fully differential type operational amplifier 30 and simultaneously cooperates with the capacitive element 22 to have a function of a low-pass filter. That is, the filter circuit 20 is utilized effectively, so that it is possible to construct a functional signal processing circuit that efficiently executes setting of a gain of the amplification circuit that includes the operational amplifier 30 and elimination of noise that influences sampling of the differential input type AD converter 60.

Furthermore, a value twice as much as a capacitance value C of the capacitive element 22 of the balance type filter circuit 20 contributes to setting of a cutoff frequency, so that it is possible to suppress a cost increase that is caused by an increase in a dimension of the capacitive element 22 in setting of a cutoff frequency Fc and thereby integrate the filter circuit 20.

Moreover, the filter circuit 20 is provided as the ladder resistance circuits 200, 201 where the plurality of resistance elements 20-1 to 20-5, 21-1 to 21-5 are connected in series, and the connection terminals P1-1 to P1-4, P2-1 to P2-4 of the resistance elements that are connected back and forth are appropriately selected to connect the capacitive element 22 therebetween, so that it is possible to efficiently execute both setting of a gain of the amplification circuit that includes the fully differential type operational amplifier 30 and setting of a cutoff frequency Fc where a frequency of a sampling signal Fs of the differential input type AD converter 60 is taken into consideration.

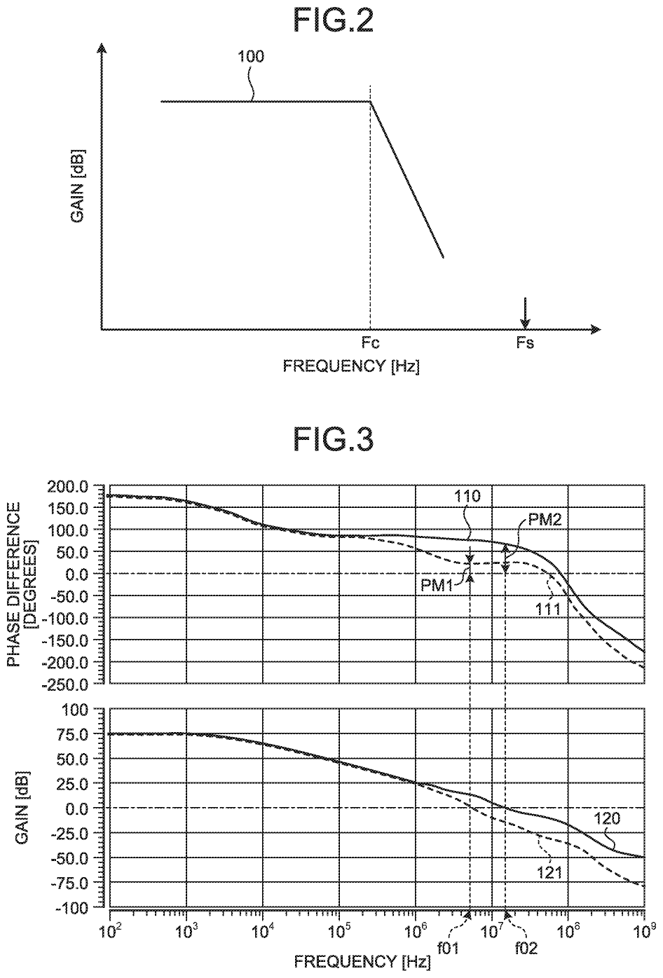

FIG. 2 is a diagram schematically illustrating a frequency characteristic of the filter circuit 20. A horizontal axis is a frequency [Hz], a vertical axis is a gain [dB], and a frequency characteristic of the filter circuit 20 is represented by a solid line 100. A connection position of the capacitive element 22 in the ladder resistance circuits 200, 201 is adjusted, so that a cutoff frequency Fc of the filter circuit 20 is set by a resistance value of a resistor from the input terminal 10 to the connection position of the capacitive element 22 and a capacitance value C of the capacitive element 22.

As illustrated in FIG. 2, a cutoff frequency Fc of the filter circuit 20 is set so as to be a sufficiently low frequency with respect to a sampling frequency Fs of the differential input type AD converter 60. Thereby, noise with a frequency that is close to a sampling frequency Fs that is included in an input signal that is supplied between the input terminals 10, 11 of the filter circuit 20 is eliminated. Even in a case where timing of sampling in the differential input type AD converter 60 is slightly shifted, a variation of an output of the differential input type AD converter 60 is avoided by eliminating noise with a frequency that approximates a sampling frequency Fs, so that strict control of timing of sampling in the differential input type AD converter 60 is not needed.

FIG. 3 is a Bode diagram for schematically explaining a relationship between a configuration of the filter circuit 20 and a phase margin of the amplification circuit that includes the fully differential type operational amplifier 30. An upper part is a phase diagram illustrating a relationship between a frequency [Hz] and a phase difference [degrees] and a lower part is a gain diagram illustrating a relationship between a frequency [Hz] and a gain [dB]. A simulation is provided where a connection position of the capacitive element 22 is changed while a product of a capacitance value C of the capacitive element 22 and a resistance value of a resistor from the input terminal 10 to a connection position where the capacitive element 22 is connected, that is, a cutoff frequency Fc of the filter circuit 20, is kept constant.

Solid lines 110 and 120 in FIG. 3 represent a case where the capacitive element 22 is connected between the connection terminals P1-1 and P1-2, and broken lines 111 and 121 represent a case where the capacitive element 22 is connected between the output terminals 24 and 25.

A phase margin PM2 in a case as indicated by the solid line 110, that is, a case where the capacitive element 22 is connected to the connection terminals P1-1, P1-2 that are close to the input terminals 10, 11, that is, a phase difference at a frequency f02 where a gain is 0 dB is greater than a phase margin PM1 in a case where the capacitive element 22 is connected between the output terminals 24, 25, that is, a phase difference at a frequency f01 where a gain is 0 dB. However, resistance values from the input terminals 10, 11 to connection terminals are small, so that a capacitance value of the capacitive element 22 has to be increased so as to provide an identical cutoff frequency Fc of the filter circuit 20.

On the other hand, in a case where connection terminals of the capacitive element 22 are close to the output terminals 24, 25, resistance values from the input terminals 10, 11 to connection terminals where the capacitive element 22 is connected are large, so that it is possible to decrease a capacitance value C of the capacitive element 22 so as to provide an identical cutoff frequency Fc but a phase margin is decreased. That is, a trade-off relationship is caused between a phase margin and a capacitance value C of the capacitive element 22.

It is possible to adjust connection positions of the capacitive element 22 in the ladder resistance circuits 200, 201 by taking into consideration a gain that is needed for the amplification circuit that is configured by using the fully differential type operational amplifier 30 and a needed phase margin. The ladder resistance circuits 200, 201 where the plurality of resistance elements 20-1 to 20-5, 21-1 to 21-5 are connected in series are provided in the filter circuit 20 and the plurality of connection terminals P1-1 to P1-4, P2-1 to P2-4 are preliminarily prepared as connection terminals of the capacitive element 22, so that selection of connection positions of the capacitive element 22 is facilitated while a trade-off relationship between a phase margin and a capacitance value C of the capacitive element 22 is taken into consideration.

### Second Embodiment

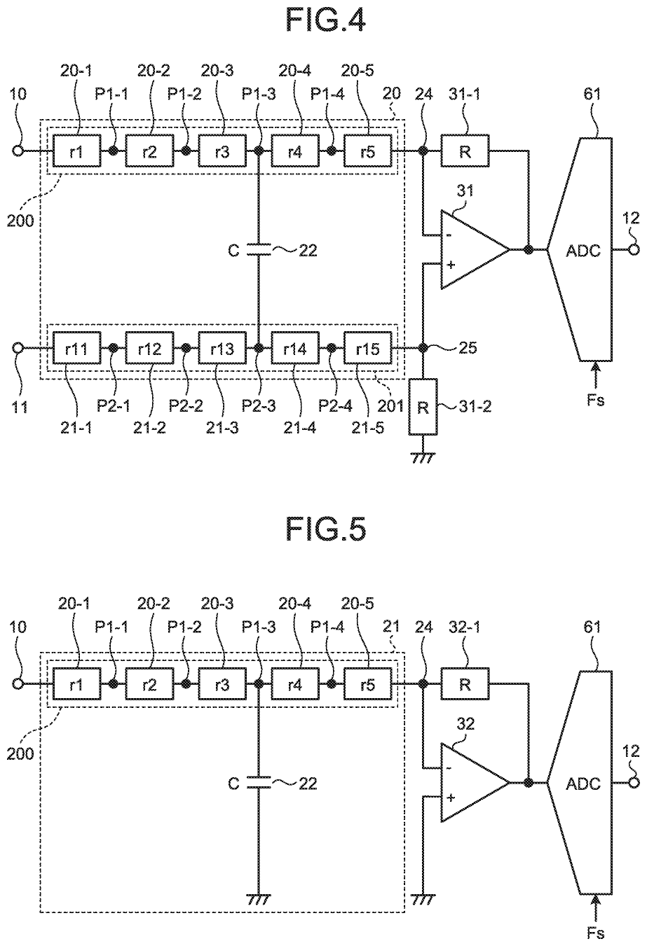

FIG. 4 is a diagram illustrating a signal processing device according to a second embodiment. A component that corresponds to that of an embodiment as already described will be provided with an identical sign and a duplicative descriptions will be provided only in a needed case. Hereinafter, the same applies. The present embodiment has a single phase output operational amplifier 31 with an inverting input end (−) that is connected to the output terminal 24 of the filter circuit 20 and a non-inverting input end (+) that is connected to the output terminal 25. It has a feedback resistor 31-1 between an output end and an inverting input end (−) of the single phase output operational amplifier 31. A resistor 31-2 is connected between a non-inverting input end (+) of the single phase output operational amplifier 31 and ground.

An output signal of the single phase output operational amplifier 31 is supplied to a single phase input type AD converter 61. The single phase input type AD converter 61 samples an output signal of the single phase output operational amplifier 31 depending on a sampling signal Fs and supplies an output signal that has been converted into a digital signal to the output terminal 12.

Also in the present embodiment, the filter circuit 20 has both functions of setting of a gain of an amplification circuit that includes the single phase output operational amplifier 31 and elimination of noise that is included in an input signal that is applied between the input terminals 10, 11. A gain of the amplification circuit that includes the single phase output operational amplifier 31 is set by a ratio of a total value of resistance values of the resistance elements 20-1 to 20-5 of the ladder resistance circuit 200 to a resistance value R of the feedback resistor 31-1 and a ratio of a total value of resistance values of the resistance elements 21-1 to 21-5 of the ladder resistance circuit 201 to a resistance value R of the resistor 31-2.

A cutoff frequency Fc of the filter circuit 20 for a differential input signal is represented by formula (2).

Fc=1/2π×R1×2×C (2)

Herein, R1 represents a resistance value from the input terminal 10 to the connection terminal P1-3 where the capacitive element 22 is connected, and C represents a capacitance value of the capacitive element 22.

According to the present embodiment, a value twice as much as a capacitance value C of the capacitive element 22 contributes to setting of a cutoff frequency Fc as indicated in formula (2), similarly to the first embodiment. Hence, it is possible to suppress a capacitance value of the capacitive element 22, so that it is possible to reduce a dimension of the capacitive element 22. It is possible to select a resistance value R1 and a capacitance value C appropriately and thereby eliminate noise that influences sampling of the single phase input type AD converter 61.

Furthermore, a total value of resistances of the respective resistance elements 20-1 to 20-5, 21-1 to 21-5 of the ladder resistance circuits 200, 201 of the filter circuit 20 simultaneously serves a function to set a gain of the amplification circuit that includes the single phase output operational amplifier 31. That is, the filter circuit 20 is utilized effectively, so that it is possible to construct a functional signal processing circuit that includes the single phase output operational amplifier 31 and the single phase input type AD converter 61.

### Third Embodiment

FIG. 5 is a diagram illustrating a signal processing device according to a third embodiment. The present embodiment has a single phase output operational amplifier 32 with an inverting input end (−) that is connected to the output terminal 24 of a filter circuit 21. It has a feedback resistor 32-1 between an output end and an inverting input end (−) of the single phase output operational amplifier 32. A non-inverting input end (+) of the single phase output operational amplifier 32 is grounded.

An output signal of the single phase output operational amplifier 32 is supplied to the single phase input type AD converter 61. The single phase input type AD converter 61 samples an output signal of the single phase output operational amplifier 32 depending on a sampling signal Fs and supplies an output signal that has been converted into a digital signal to the output terminal 12.

Also in the present embodiment, the filter circuit 21 has both functions of setting of a gain of an amplification circuit that includes the single phase output operational amplifier 32 and elimination of noise that is included in an input signal that is applied between the input terminals 10, 11. A gain of the amplification circuit that includes the single phase output operational amplifier 32 is set by a ratio of a resistance value of the ladder resistance circuit 200, that is, a total value of resistance values of the resistance elements 20-1 to 20-5 (=r1+r2+r3+r4+r5) and a resistance value R of the feedback resistor 32-1.

A cutoff frequency Fc of the filter circuit 21 is represented by formula (3).

Fc=1/2π×R1×C (3)

Herein, R1 represents a resistance value from the input terminal 10 to the connection terminal P1-3 where the capacitive element 22 is connected and C represents a capacitance value of the capacitive element 22.

In the present embodiment, as indicated in formula (3), the capacitive element 22 contributes to setting of a cutoff frequency Fc by one time as much as a capacitance value C. However, a resistance circuit that composes the filter circuit 21 is only the ladder resistance circuit 200, so that it is possible to reduce resistance elements that compose the filter circuit 21. It is possible to adjust a resistance value R1 and a capacitance value C by taking into consideration a frequency of a sampling signal Fs of the single phase input type AD converter 61 and thereby eliminate noise that influences sampling of the single phase input type AD converter 61.

It is possible to set a needed gain of the amplification circuit that includes the single phase output operational amplifier 32 by a ratio of a resistance value R of the feedback resistor 32-1 and a resistance value of the ladder resistance circuit 200, that is, a total value of resistance values of the resistance elements 20-1 to 20-5 (=r1+r2+r3+r4+r5). Thereby, the filter circuit 20 is utilized effectively, so that it is possible to construct a functional signal processing circuit that includes an amplification circuit and an AD converter.

Additionally, for the differential input type AD converter 60 or the single phase input type AD converter 61 as already described, it is possible to use a variety of AD converters that sample an input signal by a sampling signal Fs with a predetermined frequency and execute AD conversion thereof, such as, for example, a ΔΣ type AD converter or a successive approximation type AD converter.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A signal processing circuit, comprising:
a filter circuit that includes
a first resistor that is provided between a first input terminal and a first connection terminal,
a second resistor that is provided between the first connection terminal and a first output terminal, and
a capacitive element with one terminal that is connected to the first connection terminal; and
an amplification circuit that has a first input end connected to the first output terminal and an output end and is provided with a feedback resistor that is connected between the first input end and the output end,
wherein a cutoff frequency of the filter circuit is set by a resistance value of the first resistor and a capacitance value of the capacitive element and a gain of the amplification circuit is set by a ratio of a total value of resistance values of the first resistor and the second resistor and a resistance value of the feedback resistor.

2. The signal processing circuit according to claim 1, comprising
an AD conversion circuit that samples an output signal of the amplification circuit by a sampling signal with a predetermined frequency and converts it into a digital value, wherein
the cutoff frequency of the filter circuit is set at a frequency that is less than the predetermined frequency.

3. The signal processing circuit according to claim 2, wherein the AD conversion circuit is a single phase input type AD conversion circuit where the output signal of the amplification circuit is supplied thereto.

4. The signal processing circuit according to claim 1, wherein the first resistor and the second resistor are composed of a plurality of resistance elements that are connected in series.

5. The signal processing circuit according to claim 4, wherein resistance values of the plurality of resistance elements are set at identical values.

6. The signal processing circuit according to claim 1, wherein the filter circuit includes:
a third resistor that has a resistance value that is identical to that of the first resistor and is provided between a second input terminal and a second connection terminal; and
a fourth resistor that has a resistance value that is identical to that of the second resistor and is provided between the second connection terminal and a second output terminal, and
another terminal of the capacitive element is connected to the second connection terminal.

7. The signal processing circuit according to claim 6, wherein the amplification circuit includes:
a second input end that is connected to the second output terminal;
a second output end that outputs a signal with a phase opposite to that of an output signal that is output from the output end; and
a second feedback resistor that is connected between the second output end and the second input end.

8. The signal processing circuit according to claim 7, wherein the AD conversion circuit is a differential input type AD conversion circuit where output signals from the first output end and the second output end of the amplification circuit are supplied thereto.

9. The signal processing circuit according to claim 6, wherein the amplification circuit includes:
a second input end that is connected to the second output terminal; and
a fifth resistor that is connected between the second input end and ground.

10. A signal processing circuit, comprising:
a filter circuit that includes
a first resistor that is provided between a first input terminal and a first connection terminal;
a second resistor that is provided between the first connection terminal and a first output terminal;
a third resistor that is provided between a second input terminal and a second connection terminal;
a fourth resistor that is provided between the second connection terminal and a second output terminal; and
a capacitive element with one terminal that is connected to the first connection terminal and another terminal that is connected to the second connection terminal; and
an amplification circuit that has a first input end connected to the first output terminal, a second input end connected to the second output terminal, a first output end and a second output end and is provided with a first feedback resistor that is connected between the first input end and the first output end and a second feedback resistor that is connected between the second input end and the second output end, wherein
a cutoff frequency of the filter circuit is set by resistance values of the first resistor and the third resistor and a capacitance value of the capacitive element, and
a gain of the amplification circuit is set by a ratio of a total value of resistance values of the first resistor and the second resistor to a resistance value of the first feedback resistor and a ratio of a total value of resistance values of the third resistor and the fourth resistor to a resistance value of the second feedback resistor.

11. The signal processing circuit according to claim 10, comprising
an AD conversion circuit that samples an output signal of the amplification circuit by a sampling signal with a predetermined frequency and converts it into a digital value, wherein
the cutoff frequency of the filter circuit is set at a frequency that is less than the predetermined frequency.

12. The signal processing circuit according to claim 11, wherein the AD conversion circuit is a differential input type AD conversion circuit where output signals from the first output end and the second output end of the amplification circuit are supplied thereto.

13. The signal processing circuit according to claim 10, wherein the first resistor and the third resistor have resistance values that are identical values.

14. The signal processing circuit according to claim 13, wherein the first resistor and the third resistor are composed of a plurality of resistance elements that are connected in series.

15. The signal processing circuit according to claim 14, wherein resistance values of the plurality of resistance elements are set at identical values.

16. A signal processing circuit, comprising:
a filter circuit that includes
a first resistor that is provided between an input terminal and a connection terminal,
a second resistor that is provided between the connection terminal and an output terminal, and
a capacitive element with one terminal that is connected to the connection terminal and another terminal that is grounded; and
an amplification circuit that has a first input end that is grounded, a second input end connected to the output terminal and an output end and is provided with a feedback resistor that is connected between the second input end and the output end, wherein
a cutoff frequency of the filter circuit is set by a resistance value of the first resistor and a capacitance value of the capacitive element, and
a gain of the amplification circuit is set by a ratio of a total value of resistance values of the first resistor and the second resistor and a resistance value of the feedback resistor.

17. The signal processing circuit according to claim 16, comprising
an AD conversion circuit that samples an output signal of the amplification circuit by a sampling signal with a predetermined frequency and converts it into a digital value, wherein
the cutoff frequency of the filter circuit is set at a frequency that is less than the predetermined frequency.

18. The signal processing circuit according to claim 17, wherein the AD conversion circuit is a single phase input type AD conversion circuit where an output signal of the amplification circuit is supplied thereto.

19. The signal processing circuit according to claim 16, wherein the first resistor and the second resistor are composed of a plurality of resistance elements that are connected in series.

20. The signal processing circuit according to claim 19, wherein resistance values of the plurality of resistance elements are set at identical values.
